(19) United States
(12) Patent Application Publication
(10) Pub. No.: US 2013/0019678 A1
(43) Pub. Date: Jan. 24, 2013

(54) Limiting travel of proof mass within frame of MEMS device

(71) Applicants: Dennis M. Lazaroff, Corvallis, OR (US); Rodney L. Alley, Albany, OR (US); Brian D. Horneijer, Corvallis, OR (US); John L. Williams, Philomath, OR (US); Donald J. Milligan, Corvallis, OR (US)

(72) Inventors: Dennis M. Lazaroff, Corvallis, OR (US); Rodney L. Alley, Albany, OR (US); Brian D. Horneijer, Corvallis, OR (US); John L. Williams, Philomath, OR (US); Donald J. Milligan, Corvallis, OR (US)

(21) Appl. No.: 13/189,369

(22) Filed: Jul. 22, 2011

(51) Int. Cl. G01C 19/56; H05K 13/04

(52) U.S. Cl. 73/504.12; 29/832

(57) ABSTRACT

A micro electromechanical systems (MEMS) device includes a proof mass and a frame. The proof mass is to movably travel within the frame.

### BACKGROUND

Micro electromechanical systems (MEMS) devices are generally very small mechanical devices driven by electricity. MEMS devices can also be referred to as micromachines and micro systems technology (MST) devices. In some types of MEMS devices, a proof mass, which is also referred to as a seismic mass, is permitted to movably travel within a frame, for sensing, actuation, and/or other purposes. For instance, in an accelerometer, travel of the proof mass within the frame provides for a way to detect the acceleration that the accelerometer is undergoing.

### BRIEF DESCRIPTION OF THE DRAWINGS

FIGS. 1A and 1B are cross-sectional top view and front view diagrams, respectively, of an example micro electromechanical systems (MEMS) device in which a proof mass is to movably travel within a frame.

FIGS. 2A, 2B, and 2C are diagrams of different example portions of a MEMS device in which movable travel of a proof mass within a frame is limited, in accordance with a first example technique.

FIG. 3 is a flowchart of an example method for at least partially fabricating the MEMS device of FIG. 2A, 2B, or 2C.

FIG. 4 is a diagram of an example portion of a MEMS device in which movable travel of a proof mass within a frame is limited, in accordance with a second example technique.

FIG. 5 is a flowchart of an example method for at least partially fabricating the MEMS device of FIG. 4.

FIG. 6 is a diagram of an example portion of a MEMS device that results after performing the method of FIG. 5.

FIG. 7 is a flowchart of an example method for at least partially fabricating a MEMS device in which movable travel of a proof mass within a frame is limited.

FIG. 8 is a diagram of an example portion of a MEMS device that results after performing the method of FIG. 7, in accordance with a third example technique.

FIG. 9 is a flowchart of an example method for at least partially fabricating a MEMS device in which movable travel of a proof mass within a frame is limited.

FIG. 10 is a diagram of an example portion of a MEMS device that results after performing the method of FIG. 9, in accordance with a fourth example technique.

FIG. 11 is a flowchart of an example method that summarizes the fabrication process of the methods of FIGS. 3, 5, 7, and 9.

FIG. 12 is a block diagram of an example system.

### DETAILED DESCRIPTION

As noted in the background section, some types of micro electromechanical systems (MEMS) devices include a proof mass and a frame. The proof mass is permitted to movably travel within the frame. Existing such MEMS devices, however, typically permit the proof mass to movably travel within the frame more than fifty micron on-axis, due to limitations in known fabrication techniques to fabricating such MEMS devices.

For example, a flexure between the proof mass and the frame may be destroyed or otherwise impaired during the fabrication of such a MEMS device in accordance with a known fabrication technique that attempts to limit this distance to no more than fifty micron. As such, the MEMS device is nonfunctional and effectively unusable.

However, at the same time, permitting the proof mass to movably travel within the frame more than fifty micron can be disadvantageous. A flexure, which is a type of linear spring, is usually used to attach the proof mass to the frame of a MEMS device. When the proof mass can movably travel within the frame more than fifty micron, undue stress on the flexure can result in the premature failure of the MEMS device.

Furthermore, in general, the greater the distance that the proof mass can movably travel within the frame, the higher the acceleration that an accelerometer is undergoing that can be detected. This permits the accelerometer to be used in more scenarios than if the travel of the proof mass within the frame is limited, which is unintuitively disadvantageous. In particular, such an accelerometer may become subject to export controls and other regulations.

Disclosed herein are techniques for limiting the travel of a proof mass within a frame of a MEMS device. A MEMS device includes at least a proof mass and a frame enclosing the proof mass and within which the proof mass is able to movably travel. A proof mass bumper extends outwards from the proof mass towards the frame, and a frame bumper located at least partially opposite the proof mass bumper extends inwards from the frame towards the proof mass bumper. In one implementation, just the proof mass bumper or just the frame bumper is present. Disclosed herein are techniques to limit the distance between the bumpers and that defines the travel limit of the proof mass within the frame to no more than fifty micron, without the resulting MEMS device being nonfunctional and thus without this MEMS device being unusable.

More specifically, testing of existing fabrication techniques has demonstrated that a MEMS device in accordance with such techniques is manufactured so that the distance between the proof mass and the frame is no greater than about fifty micron, the resulting MEMS device is nonfunctional and hence unusable. In the type of MEMS device in relation to which such testing has been performed, this is particularly because a flexure between the proof mass and the frame becomes destroyed or otherwise impaired when limiting this distance to no greater than about fifty micron. By comparison, the techniques disclosed herein permit a MEMS device to be manufactured so that the distance can be limited to no greater than about fifty micron, without the resulting MEMS device being nonfunctional and thus without the resulting MEMS device being unusable.

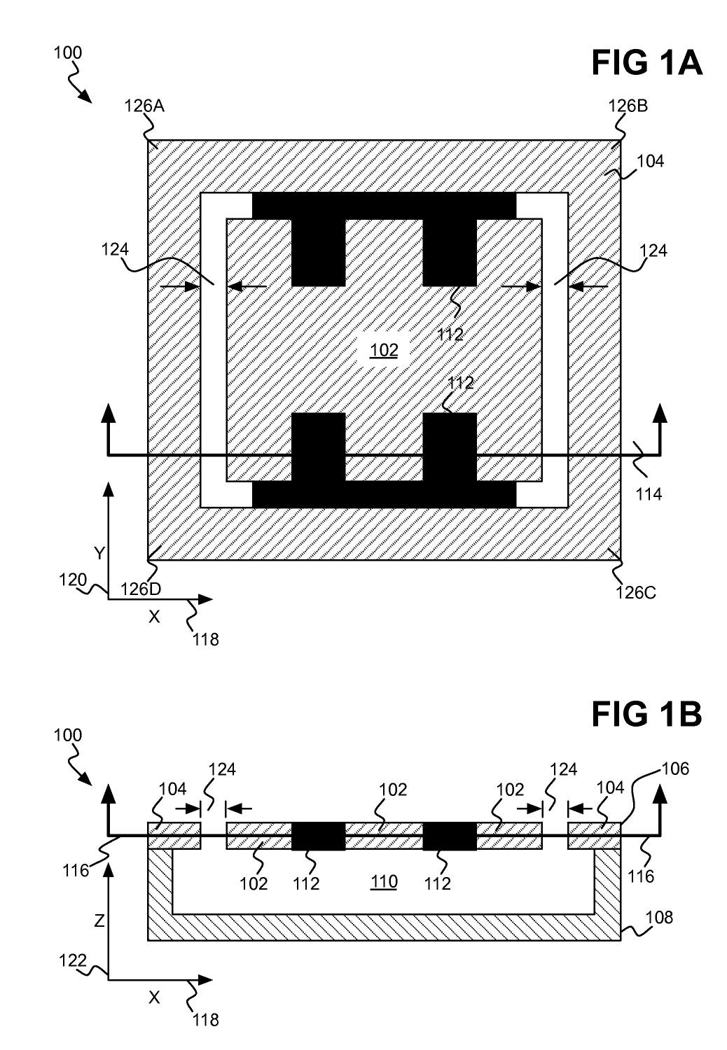

FIGS. 1A and 1B show an example MEMS device 100. FIG. 1A is a cross-sectional top view of the MEMS device 100 over an x-y plane defined by an x-axis 118 and a y-axis 120, whereas FIG. 1B is a cross-sectional front view of the MEMS device 100 over an x-z plane defined by the x-axis 118 and a z-axis 122. The cross-sectional top view of FIG. 1A is defined by the sectional line 116 of FIG. 1B, and the cross-sectional front view of FIG. 1B is defined by the sectional line 114 of FIG. 1A. The MEMS device 100 can have four corners 126A, 126B, 126C, and 126D, which are collectively referred to as the corners 126.

The MEMS device 100 includes a proof mass 102 and a frame 104. The frame 104 encloses the proof mass 102 within the x-y plane of FIG. 1A. The proof mass 102 is able to movably travel within the frame 104. The movable travel of the proof mass 102 within the frame 104 that is of interest in the example of FIGS. 1A and 1B is along the x-axis 118, which is referred to as single-axis travel of the proof mass 102. The limit to this movable travel is defined by a distance 124 between a portion of the proof mass 102 and a portion of the frame 104 to either side of the proof mass 102 along the x-axis 118, as is described in detail below in relation to several example implementations of the MEMS device 100.

The MEMS device 100 is depicted in FIG. 1 in generalized form as including a flexure 112 that is a type of linear spring. The actual shape and/or configuration of the flexure 112 can vary from that depicted in FIG. 1. The flexure 112 movably attaches the proof mass 102 to the frame 104. The flexure 112 is flexible, which permits the proof mass 102 to movably travel within the frame 104 along at least the x-axis 118. By comparison, both the proof mass 102 and the frame 104 are rigid.

The proof mass 102 and the frame 104 can be fabricated from a proof mass wafer 106, such as a silicon wafer. The proof mass wafer 106 can be indirectly or directly attached to a substrate wafer 108, which also may be a silicon wafer. The substrate wafer 108 defines a cavity 110, so that the proof mass 102 is not in contact with the substrate wafer 108. As such, the proof mass 102 may just be in contact with the flexure 112 in a neutral position in which the MEMS device 100 is at rest and not undergoing any acceleration.

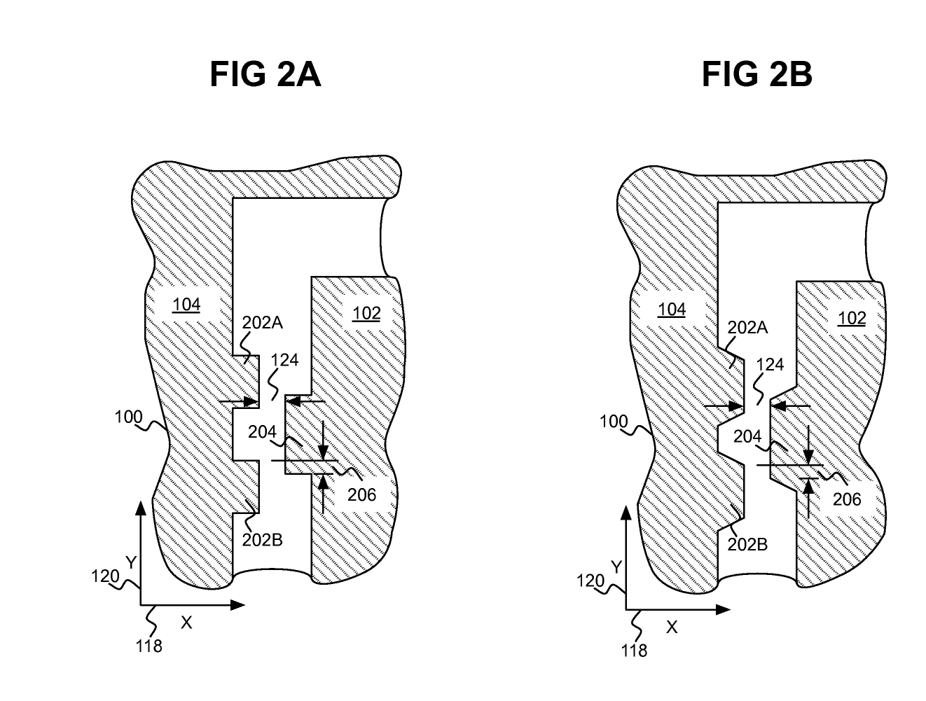

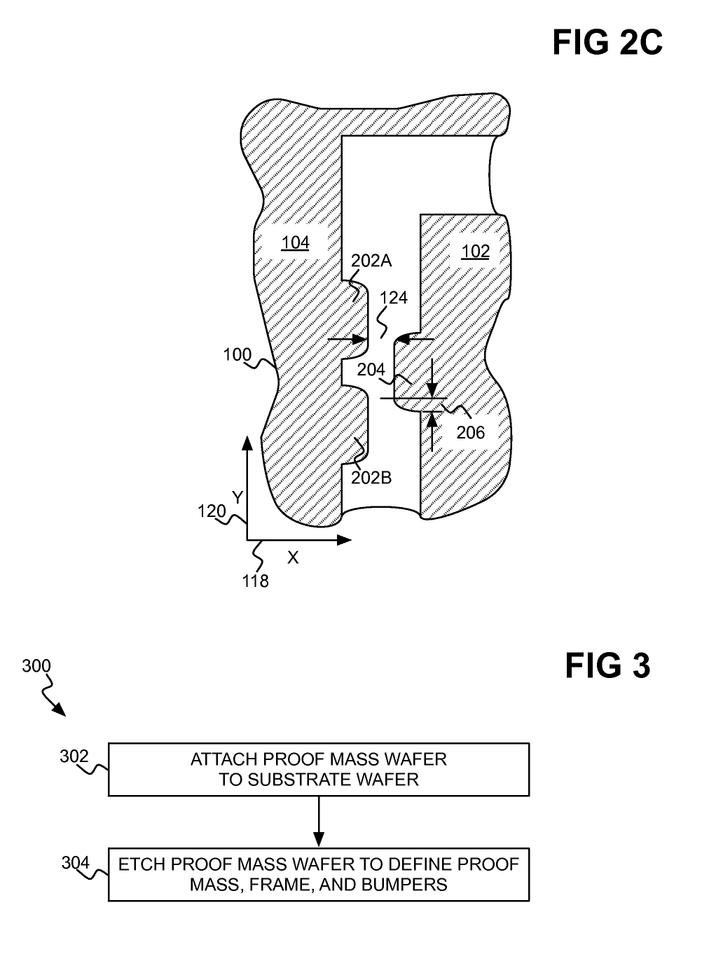

A first example technique by which the distance 124 that defines the movable travel limit is limited to no more than fifty micron is described with reference to FIGS. 2A, 2B, 2C, and 3. FIGS. 2A, 2B, and 2C shows different examples of a portion of the MEMS device 100 at the corner 126A thereof, within the x-y plane defined by the x-axis 118 and the y-axis 120. More generally, FIGS. 2A, 2B, and 2C are representative of each corner 126 of the MEMS device 100.

In each of FIGS. 2A, 2B, and 2C, a pair of bumper portions 202A and 202B, which are collectively referred to as the frame bumper 202, extend inwards from the frame 104 towards the proof mass 102 along the x-axis 118. Similarly, a bumper 204, which can be referred to as a proof mass bumper 204, extends outwards from the proof mass 102 towards the frame 104 along the x-axis 118. In a different implementation, the proof mass bumper 204 may have multiple bumper portions, instead of or in addition to the frame bumper 202 having multiple bumper portions.

The difference among FIGS. 2A, 2B, and 2C is the shape of the bumpers 202 and 204. In FIG. 2A, the bumpers 202 and 204 are rectangular in shape. In FIG. 2B, the bumpers 202 and 204 are trapezoidal in shape. In FIG. 2C, the bumpers 202 and 204 are rounded or curved in shape. Being trapezoidal or rounded or curved in shape may enable the bumpers 202 and 204 to be resistance to chipping when they come into contact with one another.

The distance 124 that defines the travel limit of the proof mass 102 within the frame 104 is itself defined between the bumpers 202 and 204. The frame bumper 202 and the proof mass bumper 204 are offset from but overlap one another, as defined by a distance 206, which may be ten, twenty, or thirty microns in varying implementations. Specifically, the frame bumper portions 202A and 202B overlap different parts of the proof mass bumper 204. It has been determined that overlapping bumpers 202 and 204 permit the fabrication of the MEMS device 100 in a way that allows for decreasing the distance 124 so that the distance 124 is no greater than fifty micron. The distance 124 has been decreased to as low as ten, twenty, and thirty microns in different experimental tests.

In this respect, the MEMS device 100 differs from existing MEMS devices, in which there are either no bumpers, or the bumpers are positioned directly opposite to and aligned with one another such that they are not offset in relation to one another. It has been determined that typical fabrication of such an existing MEMS device cannot be achieved in a way that allows for decreasing the distance 124 to no greater than fifty micron. Rather, such an existing MEMS device can just have the distance 124 decreased to greater than fifty micron.

FIG. 3 shows an example method 300 for at least partially fabricating the MEMS device 100 of FIG. 2A, 2B, or 2C. Parts 302 and 304 can be performed in the order indicated in FIG. 3. The proof mass wafer 106 is attached to the substrate wafer 108 (302). The substrate wafer 108 already has had the cavity 110 formed therein.

The proof mass wafer 106 is etched to define the proof mass 102, the frame 104, and the bumpers 202 and 204 (304). The definition of the bumpers 202 and 204 can occur at the same time the proof mass 102 and the frame 104 are defined. As such, the bumpers 202 and 204 are formed within the same etching process in which the proof mass 102 and the frame 104 are formed. The etching process can be a reactive ion etch or Bosch process, and/or another type of fabrication process.

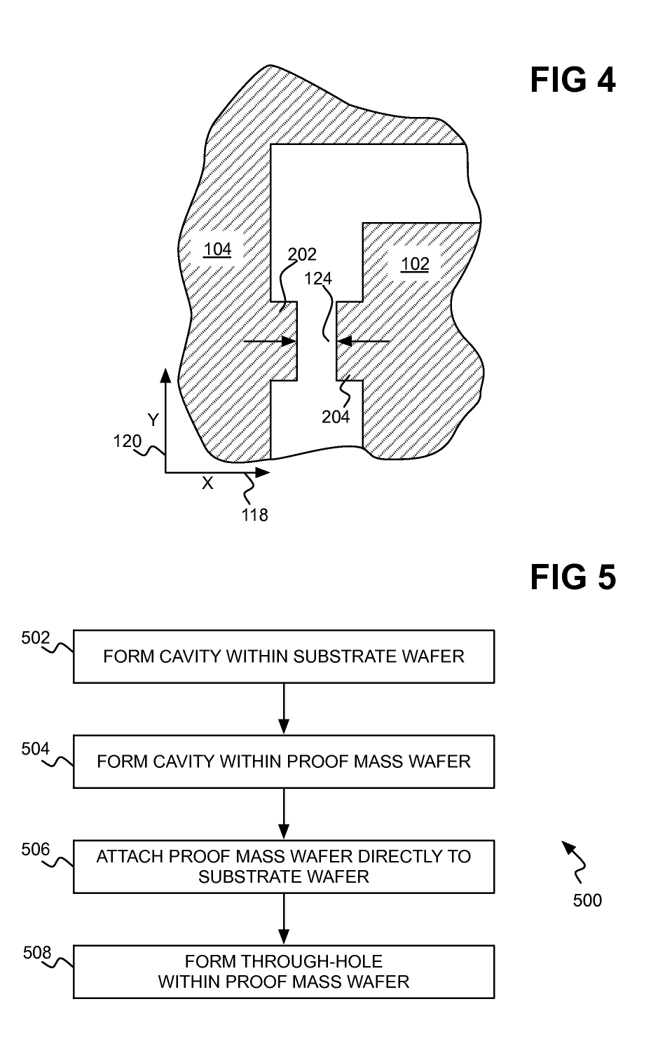

A second example technique by which the distance 124 that defines the movable travel limit of the proof mass 102 is limited to no more than fifty micron in relation to the frame 104 is described with reference to FIGS. 4, 5, and 6. FIG. 4 shows an example of a portion of the MEMS device 100 at the corner 126A thereof, within the x-y plane defined by the x-axis 118 and the y-axis 120. More generally, FIG. 4 is representative of each corner 126 of the MEMS device 100.

The frame bumper 202 extends inwards from the frame 104 towards the proof mass 102 along the x-axis 118. The proof mass bumper 204 extends outwards from the proof mass 102 towards the frame 104 along the x-axis 118. In the example of FIG. 4, the bumpers 202 and 204 are opposite to and aligned with one another.

The distance 124 that defines the travel limit of the proof mass 102 within the frame 104 is defined between the bumpers 202 and 204. As noted above, it has been determined that typical fabrication of an existing MEMS device having such a frame bumper and a proof mass bumper cannot be achieved in a way that allows for decreasing the distance 124 to no greater than fifty micron. However, fabrication pursuant to an example method described below permits fabrication of the MEMS device 100 of FIG. 4 such that the distance 124 can be no greater than fifty micron. In experimental tests, the distance 124 has been successfully reduced to ten, twenty, and thirty microns.

FIG. 5 shows an example method 500 for at least partially fabricating the MEMS device 100 of FIG. 4. Parts 502, 504, 506, and 508 can be performed in the order indicated in FIG. 5. Part 504 can also be performed before part 502.

The cavity 110 is formed within the substrate wafer 108 (502), and a cavity is also formed within the proof mass wafer 106 (506). The formation of the cavity 110 and the cavity within the proof mass wafer 106 can be achieved via an etching process, such as a reactive ion etch or Bosch and/or another type of fabrication process. The proof mass wafer 106 is directly attached to the substrate wafer 108 (506), such that the cavity within the proof mass wafer 106 faces the cavity 110. A through-hole extending from the bottom of the cavity within the proof mass wafer 106 is formed (508), such as via an etching process. The through-hole has a width that defines the distance 124 between the bumpers 202 and 204.

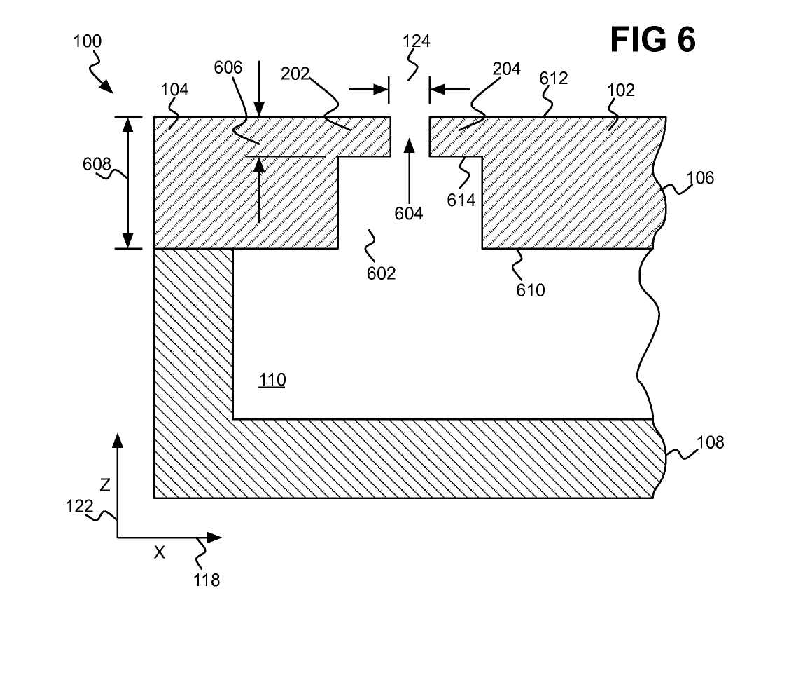

FIG. 6 shows an example of a portion of the MEMS device 100, within the x-z plane defined by the x-axis 118 and the z-axis 122, after the method 500 has been performed. Prior to attachment of the proof mass wafer 106 directly to the substrate wafer 108, the cavity 110 is formed within the substrate wafer 108, and a cavity 602 is formed within the proof mass wafer 106. The wafers 106 and 108 are then attached together, so that, as depicted in FIG. 6, the cavities 110 and 602 face one another.

A through-hole 604 is formed within proof mass wafer 106, which defines the proof mass 102, the frame 104, and the bumpers 202 and 204. The width of the through-hole 604 corresponds to and thus defines the distance 124 between the bumpers 202 and 204. The bumpers 202 and 204 have a height 606 along the z-axis 122 that can be set according to the specifications of the particular MEMS device 100 being fabricated. Likewise, the proof mass wafer 106 can itself be ground to have a height 608 along the z-axis 122 that can be sett according to the particular specifications of the MEMS device 100 being fabricated.

It is noted that in FIG. 6, the proof mass wafer 106 has a surface 610 that comes into direct contact with the substrate wafer 108. The proof mass wafer 106 further has a surface 612 opposite the surface 610. The cavity 602 extends from the surface 610 towards but not through to the surface 612. The cavity 602 is located over the cavity 110 of the substrate wafer 108, and the cavity 110 is below the bumpers 202 and 204. The through-hole 604 extends from a bottom 614 of the cavity 602 through to the surface 612.

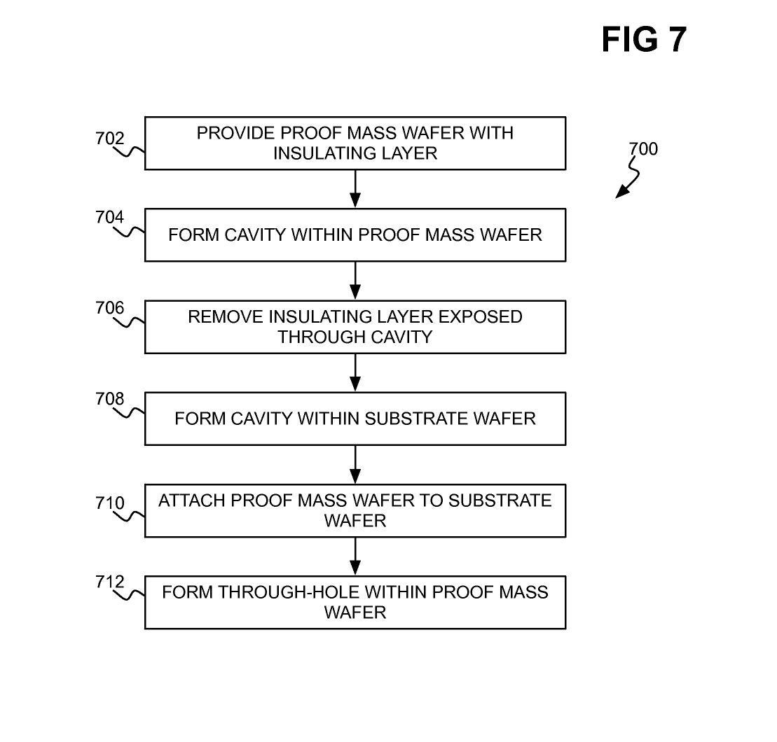

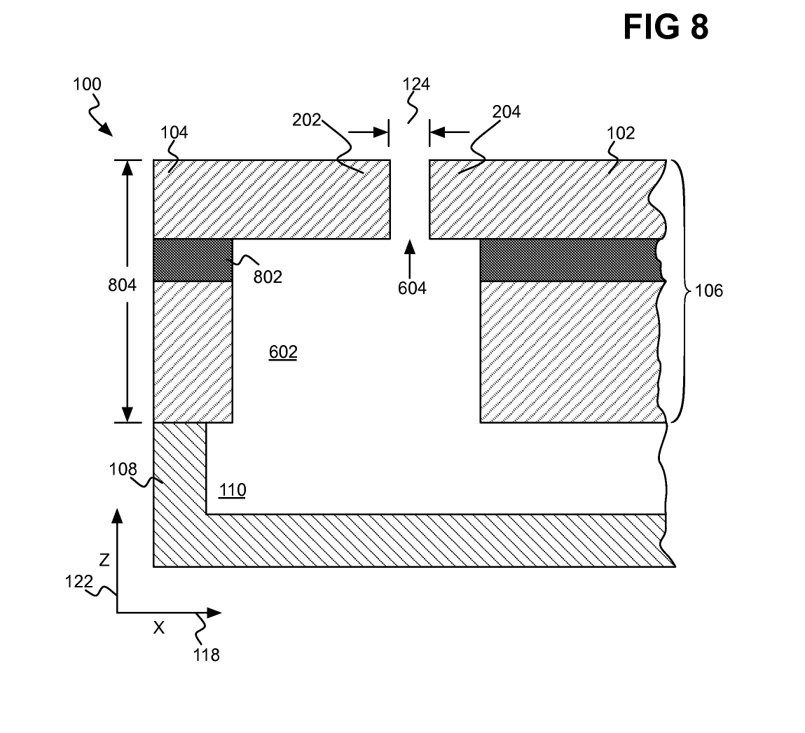

A third example technique by which the distance 124 that defines the movable travel limit of the proof mass 102 is limited to no more than fifty micron in relation to the frame 104 is described in relation to FIGS. 7 and 8. The example of the portion of the MEMS device 100 that has been described in relation to FIG. 4 is also demonstrative of the MEMS device 100 in accordance with this third technique. One difference between the second and third techniques is that the latter technique uses a proof mass wafer having a buried insulating layer.

FIG. 7 thus shows another example method 700 for at least partially fabricating the MEMS device 100 of FIG. 4. Performing parts 702, 704, 706, 708, 710, and 712 of the method 700 in the order shown in FIG. 7 provides for formation of the through-hole 604 after the wafers 106 and 108 are attached together. The cavities 110 and 602, by comparison, are formed before the wafers 106 and 108 are attached together. It is noted that part 708 may be performed before part 702, 704, or 706, however.

The proof mass wafer 106 is provided with a buried insulating layer (702). For instance, the proof mass wafer 106 may be provided as a silicon-on-insulator (SOI) wafer. As such, the insulating layer may be a buried oxide (BOX) layer. The cavity 602 is formed within the proof mass wafer 106 (704), such as by selective etching of the wafer 106, where the cavity 602 stops at the buried insulating layer. The buried insulating layer, where exposed through the cavity 602, is removed (706), such as via etching of the exposed buried insulating layer. The cavity 110 is formed within the substrate wafer 108 (708), such as also by selective etching of the wafer 108. The proof mass wafer 106 is attached to the substrate wafer 108 (710), and the through-hole 604 is then formed within the proof mass wafer 106 (712).

FIG. 8 shows an example of a portion of the MEMS device 100, with the x-z plane defined by the x-axis 118 and the z-axis 122, after the method 700 has been performed. The proof mass wafer 106 includes a buried insulating layer 802. The cavity 602 is formed within the proof mass wafer 106 to the buried insulating layer 802, and then the exposed insulating layer 802 at the bottom of the cavity 602 is removed. The cavity 110 is formed within the substrate wafer 108. The wafers 106 and 108 are attached to one another, such that the cavity 602 of the proof mass wafer 106 is adjacent to the cavity 110 of the substrate wafer 108.

The through-hole 604 is formed within the proof mass wafer 106, which defines the proof mass 102, the frame 104, and the bumpers 202 and 204. Note that the through-hole 604 is not defined within the insulating layer 802, which was previously removed. The width of the through-hole 604 corresponds to and thus defines the distance 124 between the bumpers 202 and 204. The proof mass wafer 106, including the insulating layer 802, has a height 804 along the z-axis 122 that can be set according to the particular specifications of the MEMS device 100 being fabricated.

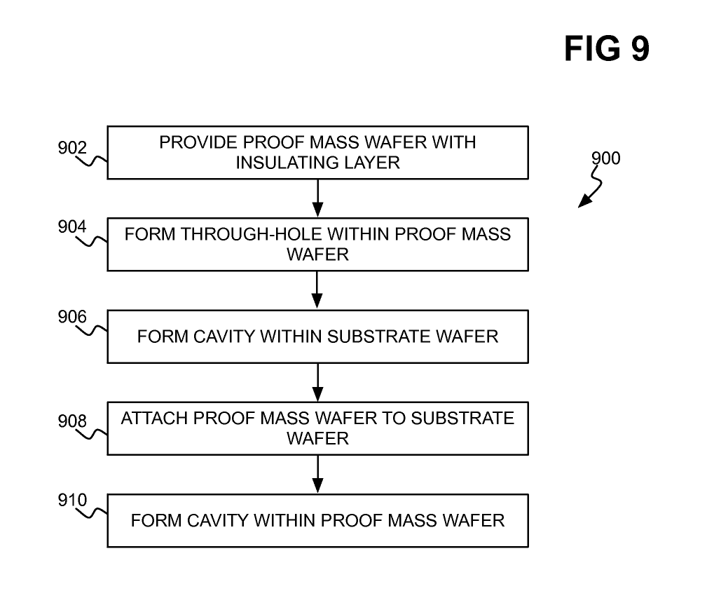

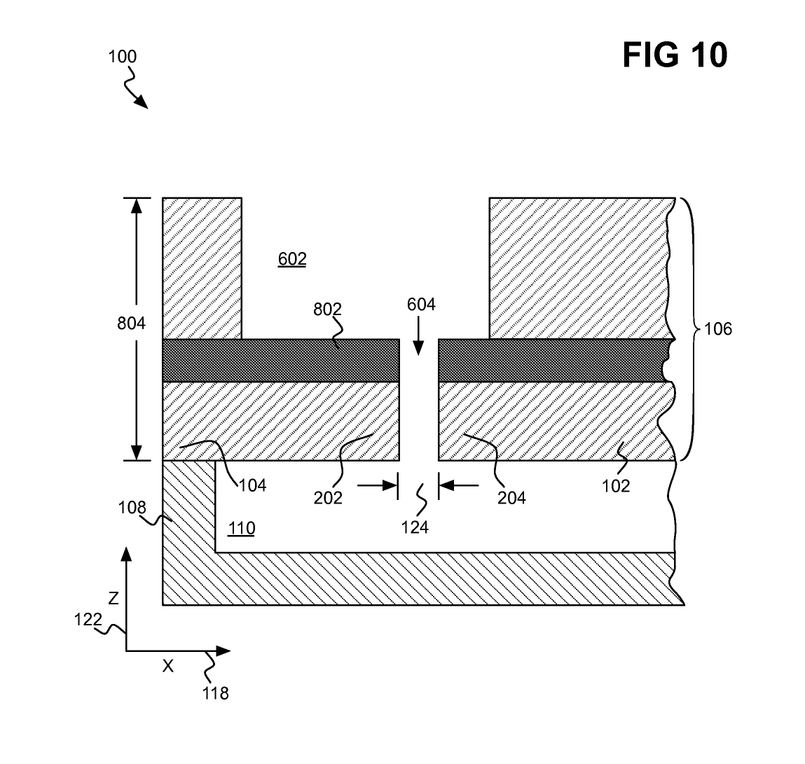

Another, fourth example technique by which the distance 124 that defines the movable travel limit of the proof mass 102 is limited to no more than fifty micron in relation to the frame 104 is described in relation to FIGS. 9 and 10. The example of the portion of the MEMS device 100 that has been described in relation to FIG. 4 is demonstrative of the MEMS device 100 in accordance with this fourth technique as well. As with the third technique, one difference between the second and fourth techniques is that the latter technique uses an insulating layer 802.

A difference between the third technique and the fourth technique is that in the former the cavity 602 of the proof mass wafer 106 is adjacent to the cavity 110 of the substrate wafer 108, whereas in the latter the cavity 602 is not adjacent to the cavity 110. Another difference between the third and fourth techniques is that in the former the through-hole 604 is formed after the wafers 106 and 108 being joined together. By comparison, in the latter the through-hole can be formed before the wafers 106 and 108 are joined together.

FIG. 9 thus shows another example method 900 for at least partially fabricating the MEMS device 100 of FIG. 1. Performing parts 902, 904, 906, 908, and 910 of the method 900 in the order shown in FIG. 9 provides for formation of the through-hole 904 before the wafers 106 and 108 are attached together. It is noted that part 910 may be performed before part 906 or 908, however.

The proof mass wafer 106 is provided with a buried insulating layer 802 (902). For instance, the proof mass wafer 106 may be provided as an SOI wafer. As such, the insulating layer may be a BOX layer. The through-hole 604 is formed within the proof mass wafer 106, including through the buried insulating layer 802 (904). The cavity 110 is formed within the substrate wafer 108 (906), such as by selective etching of the wafer 108. The proof mass wafer 106 is attached to the substrate wafer 108 (908), and the cavity 602 is formed within the proof mass wafer 106 (910), such as also by selective etching of the wafer 106, where the cavity 602 stops at the buried insulating layer 802.

FIG. 10 shows an example of a portion of the MEMS device 100, with the x-z plane defined by the x-axis 118 and the z-axis 122, after the method 700 has been performed. The proof mass wafer 106 includes the buried insulating layer 802. The through-hole 604 is formed through the proof mass wafer 106, including the buried insulating layer 802. The cavity 110 is formed within the substrate wafer 108. The wafers 106 and 108 are attached to one another. The cavity 602 is formed within the proof mass wafer 602 to the buried insulating layer 802, which remains exposed at the bottom of the cavity 602.

The cavity 602 of the proof mass wafer 106 is not adjacent to the cavity 110 of the substrate wafer 108. The through-hole 604 defines the proof mass 102, the frame 104, and the bumpers 202 and 204. Note that the through-hole 604 is defined within the insulating layer 802 as well, which was not previously removed. The width of the through-hole 604 corresponds to and thus defines the distance 124 between the bumpers 202 and 204. The proof mass wafer 106, including the insulating layer 802, has the height 804 along the z-axis 122 that can be set according to the particular specifications of the MEMS device 100 being fabricated.

Note, therefore, the differences between the MEMS device 100 of FIG. 8 in accordance with the third example technique and the MEMS device 100 of FIG. 10 in accordance with the fourth example technique. In effect, one difference between these two techniques is that the proof mass wafer 106 is “flipped” along the z-axis 122 in FIG. 10 as compared to in FIG. 8. That is, in FIG. 8, the cavity 602 of the proof mass wafer 106 is located between the through-hole 604 and the substrate wafer 108. By comparison, in FIG. 10, the through-hole 604 is located between the cavity 602 and the substrate wafer 108.

Another difference between these two techniques is that the insulating layer 802 is removed from the bottom of the cavity 602 in the third technique of FIG. 8. By comparison, the insulating layer 802 is not removed from the bottom of the cavity 602 in the fourth technique of FIG. 10. Retaining the insulating layer 802 in the MEMS device 100 of FIG. 10 can be advantageous, because it provides an etch stop when forming the cavity 602 via etching.

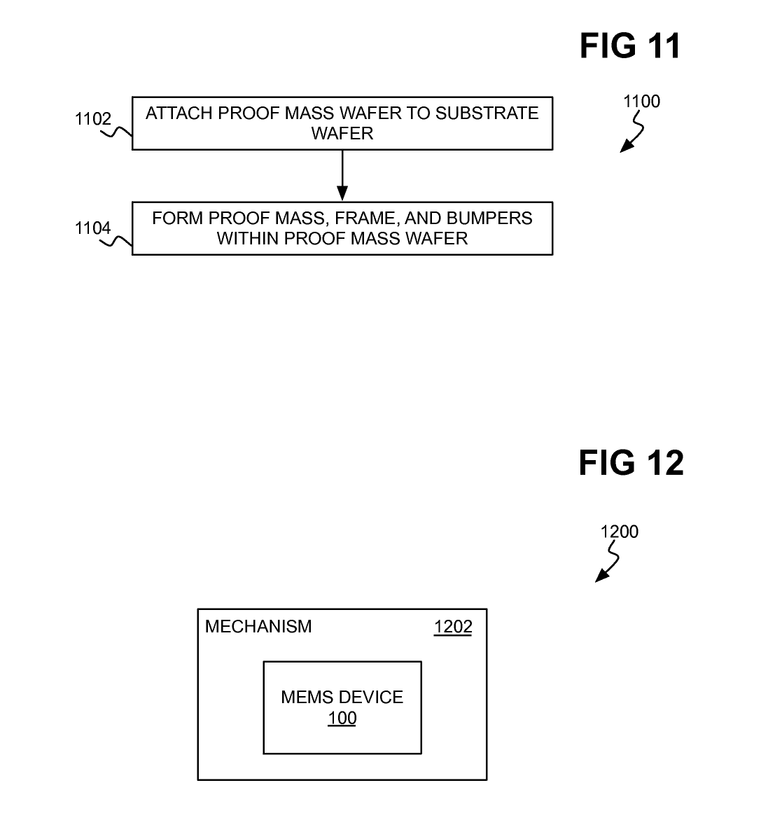

FIG. 11 shows an example method 1100 that summarizes the fabrication of the MEMS device 100 in the methods 300, 500, 700, and 900. Parts 1102 and 1104 can be performed in the order shown in FIG. 11. Parts 1102 and 1104 can also be reversed in order of performance. Furthermore some aspects of part 1104 can be performed before part 1102 is performed, whereas other aspects can be performed after part 1104 is performed.

The proof mass wafer 106 is attached to the substrate wafer 108 (1102). The proof mass 102, the frame 104, and the bumpers 202 and 204 are formed within the proof mass wafer 106 (1104). The manner by which the proof mass 102, the frame 104, and the bumpers 202 and 204 are formed can be as has been described above in relation to the method 300, 500, 700, and/or 900.

In conclusion FIG. 12 shows an example rudimentary system 1200. The system 1200 includes a mechanism 1202 that includes the MEMS device 100 that has been described. The mechanism 1202 provides a function of the system 1200, which is enabled at least in part by the MEMS device 100. For instance, the mechanism 1202 can be an accelerometer that uses the MEMS device 100 to detect acceleration, an actuator that uses the MEMS device 100 to perform actuation, or another type of mechanism that performs another type of functionality, such as gyroscope functionality.

We claim:

1. A micro electromechanical systems (MEMS) device comprising:
a proof mass;
a frame enclosing the proof mass, the proof mass to movably travel within the frame;
one or more of:
a proof mass bumper extending outwards from the proof mass towards the frame; and,
a frame bumper extending inwards from the frame towards the proof mass,
wherein the one or more of the proof mass bumper and the frame bumper define a distance corresponding to a travel limit of the proof mass within the frame, the distance being not more than fifty micron.

2. The MEMS device of claim 1, further comprising a flexure attached to both the frame and the proof mass.

3. The MEMS device of claim 1, wherein the proof mass bumper is offset to and overlaps the frame bumper.

4. The MEMS device of claim 3, wherein each of the proof mass bumper and the frame bumper are one of: rectangular in shape; trapezoidal in shape; and, curved in shape.

5. The MEMS device of claim 3, wherein the frame bumper comprises a pair of frame bumper portions separated from one another along the frame, each frame bumper portion overlapping a different part of the proof mass bumper.

6. The MEMS device of claim 1, further comprising:
a substrate wafer having a cavity below the proof mass bumper and the frame bumper; and,
a proof mass wafer attached directly to the substrate wafer and defining the proof mass, the frame, the proof mass bumper, and the frame bumper.

7. The MEMS device of claim 6, wherein the proof mass wafer has a cavity extending from a first surface of the proof mass wafer that is in contact with the substrate wafer towards but not through a second surface of the proof mass wafer that is opposite the first surface, the cavity of the proof mass wafer located over the cavity of the substrate wafer.

8. The MEMS device of claim 7, wherein the proof mass wafer further has a through-hole extending from a bottom of the cavity of the proof mass wafer to the second surface, a width of the through-hole defining the distance between the proof mass bumper and the frame bumper.

9. The MEMS device of claim 1, further comprising:
a proof mass wafer having an insulating layer, and having a first cavity below the proof mass bumper and the frame bumper; and,
a substrate wafer having a second cavity and attached to the proof mass wafer such that the first cavity and the second cavity are adjacent to one another,
wherein the proof mass wafer defines the proof mass, the frame, the proof mass bumper, and the frame bumper.

10. The MEMS device of claim 9, wherein the first cavity extends through the insulating layer,
and wherein the proof mass wafer has a through-hole extending therethrough, a width of the through-hole defining the distance between the proof mass bumper and the frame bumper.

11. The MEMS device of claim 1, further comprising:
a proof mass wafer having an insulating layer, and having a first cavity above the proof mass bumper and the frame bumper; and,
a substrate wafer having a second cavity and attached to the proof mass wafer such that the first cavity and the second cavity are not adjacent to one another,
wherein the proof mass wafer defines the proof mass, the frame, the proof mass bumper, and the frame bumper.

12. The MEMS device of claim 11, wherein the first cavity does not extend through the insulating layer.

13. The MEMS device of claim 11, wherein the proof mass wafer has a through-hole extending therethrough, a width of the through-hole defining the distance between the proof mass bumper and the frame bumper.

14. A method for fabricating a micro electromechanical systems (MEMS) device, comprising:
attaching a proof mass wafer to a substrate wafer;
forming, within at least the proof mass wafer, a proof mass and a frame enclosing the proof mass and within which the proof mass is to movably travel, such that a proof mass bumper extends outwards from the proof mass towards the frame, and such that a frame bumper at least partially opposite the proof mass bumper extends inwards from the frame towards the proof mass bumper,
wherein the proof mass and the frame are defined so that a distance between the proof mass bumper and the frame bumper defines a travel limit of the proof mass within the frame, the distance being not more than fifty micron, without the MEMS device being nonfunctional.

15. The method of claim 14, wherein forming the proof mass and the frame comprises:
etching the proof mass wafer to define the proof mass, the proof mass bumper, the frame, and the frame bumper, such that the proof mass bumper is offset to and overlaps the frame bumper.

16. The method of claim 14, wherein forming the proof mass and the frame comprises:
prior to attaching the proof mass wafer to the substrate wafer,
forming a cavity within the substrate wafer;
forming a cavity within the proof mass wafer,
wherein attaching the proof mass wafer to the substrate wafer comprises attaching the proof mass wafer directly to the substrate wafer, such that the cavity within the substrate wafer faces the cavity within the proof mass wafer;
after attaching the proof mass wafer to the substrate wafer,
forming a through-hole extending from a bottom of the cavity of the proof mass wafer, a width of the through-hole defining the distance between the proof mass bumper and the frame bumper.

17. The method of claim 14, wherein forming the proof mass and the frame comprises:
providing a proof mass wafer having an insulating layer;
forming a first cavity within the proof mass wafer to but not through the insulating layer;
forming a second cavity within the substrate wafer;
attaching the proof mass wafer to the substrate wafer such that the first cavity and the second cavity are adjacent to one another; and,
forming a through-hole within the proof mass wafer, a width of the through-hole defining the distance between the proof mass bumper and the frame bumper.

18. The method of claim 14, wherein forming the proof mass and the frame comprises:
providing a proof mass wafer having an insulating layer;
forming a through-hole within the proof mass wafer, a width of the through-hole defining the distance between the proof mass bumper and the frame bumper;
forming a second cavity within the substrate wafer;
attaching the proof mass wafer to the substrate wafer such that the first cavity and the second cavity are not adjacent to one another; and,
forming a first cavity within the proof mass wafer to and through the insulating layer.

19. A system comprising:
a mechanism to provide a function of the system; and,
a MEMS device of the mechanism, and within which movable travel of a proof mass within a frame is limited to a distance of not more than fifty micron.

20. A micro electromechanical systems (MEMS) device comprising:
a proof mass;
a frame enclosing the proof mass, the proof mass to movably travel within the frame;
a proof mass bumper extending outwards from the proof mass towards the frame; and,
a frame bumper extending inwards from the frame towards the proof mass,
wherein the proof mass bumper is offset to and overlaps the frame bumper.
